(19) United States
(12) Patent Application Publication
(10) Pub. No.: US 2026/0255891 A1
(43) Pub. Date: Aug. 27, 2026

(54) BUFFER STRUCTURES FOR MITIGATION OF DEFECTS AT DEVICE INTERFACES AND METHODS FOR PREPARING THE SAME

(71) Applicant: Nanotronics Imaging, Inc., Cuyahoga Falls, OH (US)

(72) Inventors: Philippe Bove, GIF sur Yvette (FR); Matthew C. Putman, Brooklyn, NY (US)

(73) Assignee: Nanotronics Imaging, Inc., Cuyahoga Falls, OH (US)

(21) Appl. No.: 19/545,421

(22) Filed: Feb. 20, 2026

Related U.S. Application Data
(60) Provisional application No. 63/761,995, filed on Feb. 23, 2025.
(60) Provisional application No. 63/768,274, filed on Mar. 7, 2025.

(51) Int. Cl. H10P 14/20; C30B 25/16; C30B 25/18; H10D 62/80

(52) U.S. Cl. CPC H10P 14/3251; C30B 25/165; C30B 25/183; H10D 62/875; H10P 14/2904; H10P 14/3248; H10P 14/3434

(57) ABSTRACT

The present disclosure provides a method of forming a semiconductor device, including loading a substrate into a process chamber; depositing a first buffer layer over the substrate; depositing a delta doping layer on the first buffer layer; depositing a second buffer layer on the delta doping layer, wherein the first buffer layer, the delta doping layer, and the second buffer layer form a buffer structure; and depositing an active structure epitaxial layer on the second buffer layer. The method of the present disclosure can be used to mitigate defects, including charge trapping, at semiconductor device interfaces, and to compensate for distortion of the electric field at the interface between the substrate and the active structure epitaxial layer.

### CROSS-REFERENCE TO RELATED APPLICATIONS

This application claims priority to U.S. Provisional Patent Application No. 63/761,995, filed on Feb. 23, 2025, and U.S. Provisional Patent Application No. 63/768,274, filed on Mar. 7, 2025, which are hereby incorporated by reference in their entirety.

### FIELD OF DISCLOSURE

The present disclosure generally relates to the field of semiconductors, and, more particularly, to methods of depositing a delta doping layer during epitaxial deposition to compensate for distortion of the electric field at the interface between a substrate and an active structure epitaxial layer.

### BACKGROUND

Semiconductor devices play a crucial role in modern electronics, and these devices rely on the precise control of charge carriers at material interfaces to achieve their desired electrical characteristics. Epitaxy refers to the process of growing a thin film crystal on a substrate layer. This process is commonly used in the fabrication of semiconductor devices, such as diodes and transistors. The substrate layer typically includes a material with a crystal lattice structure. The thin film crystal, also known as the epitaxial layer or active structure epitaxial layer, is often formed from another material with a different crystal lattice structure.

One challenge in the fabrication and operation of these semiconductor devices is the presence of interface states and charge trapping at material boundaries. Charge trapping refers to the capture and retention of charge carriers at these interface states, which can lead to several undesirable effects. These phenomena can occur due to lattice mismatches, impurities, or structural defects at the interface between different materials.

During the epitaxial growth process, an interface is created between the substrate layer and the active structure epitaxial layer. At this interface, the crystal lattices of the substrate layer and the active structure epitaxial layer adapt to each other through various distortions. These distortions can create defects in the crystal lattice structure, which can capture and hold electrons. These defects, also known as traps, can have a substantial impact on the performance of the semiconductor device.

In some designs, a buffer layer is grown or deposited between the substrate layer and the active structure epitaxial layer. The buffer layer is intended to minimize the number of defects resulting from the differing crystal lattice structures of the substrate layer and the active structure epitaxial layer. However, due to the inherent differences in the crystal lattice structures of the substrate layer, the buffer layer, and the active structure epitaxial layer, defects may still exist in the buffer layer, leading to a degradation of the performance of the semiconductor device.

These interface-related issues can manifest as deviations from ideal behavior, degraded device performance, increased power consumption, and reduced reliability. Efforts to mitigate these issues have included various interface engineering techniques, such as surface treatments, the use of buffer layers, and the exploration of alternative material combinations. However, there remains a need for improved methods to control and mitigate defects, including charge trapping, at semiconductor device interfaces.

### SUMMARY

In some aspects, the techniques described herein relate to a method of forming a semiconductor device, including: loading a substrate into a process chamber; depositing a first buffer layer over the substrate; depositing a delta doping layer on the first buffer layer; depositing a second buffer layer on the delta doping layer, wherein the first buffer layer, the delta doping layer, and the second buffer layer form a buffer structure; and depositing an active structure epitaxial layer on the second buffer layer.

In some aspects, the techniques described herein relate to a method, wherein the semiconductor device is vertically oriented.

In some aspects, the techniques described herein relate to a method, wherein the substrate includes silicon carbide, silicon germanium, silicon, gallium arsenide, sapphire, aluminum oxide, aluminum nitride, germanium, indium phosphide, zinc oxide, or combinations thereof.

In some aspects, the techniques described herein relate to a method, wherein the delta doping layer includes a donor material, an acceptor material, or a combination thereof.

In some aspects, the techniques described herein relate to a method, wherein the active structure epitaxial layer includes boron, aluminum, gallium, indium, carbon, silicon, germanium, tin, nitrogen, phosphorus, oxygen, sulfur, selenium, tellurium, or combinations thereof.

In some aspects, the techniques described herein relate to a method, wherein a temperature within the process chamber is about 100° C. to about 1200° C.

In some aspects, the techniques described herein relate to a method of epitaxially forming a semiconductor device, including: loading a substrate into a process chamber; depositing a buffer layer over the substrate; depositing a delta doping layer on the buffer layer, the buffer layer and the delta doping layer forming a buffer structure; and depositing an active structure epitaxial layer on the delta doping layer.

In some aspects, the techniques described herein relate to a method, wherein the semiconductor device is vertically oriented.

In some aspects, the techniques described herein relate to a method, wherein the substrate includes silicon carbide, silicon germanium, silicon, gallium arsenide, sapphire, aluminum oxide, aluminum nitride, germanium, indium phosphide, zinc oxide, or combinations thereof.

In some aspects, the techniques described herein relate to a method, wherein the delta doping layer includes a donor material, an acceptor material, or a combination thereof.

In some aspects, the techniques described herein relate to a method, further including depositing a plurality of delta doping layers, a plurality of buffer layers, or a combination thereof.

In some aspects, the techniques described herein relate to a method, wherein the active structure epitaxial layer includes boron, aluminum, gallium, indium, carbon, silicon, germanium, tin, nitrogen, phosphorus, oxygen, sulfur, selenium, tellurium, or combinations thereof.

In some aspects, the techniques described herein relate to a method, wherein a temperature within the process chamber is about 100° C. to about 1200° C.

In some aspects, the techniques described herein relate to a semiconductor device, including: a substrate; a buffer layer formed over the substrate; a delta doping layer formed over the buffer layer; and an active structure epitaxial layer formed over the delta doping layer.

In some aspects, the techniques described herein relate to a semiconductor device, wherein the semiconductor device is vertically oriented.

In some aspects, the techniques described herein relate to a semiconductor device, further including: a second buffer layer formed between the delta doping layer and the active structure epitaxial layer.

In some aspects, the techniques described herein relate to a semiconductor device, wherein the substrate includes silicon carbide, silicon germanium, silicon, gallium arsenide, sapphire, aluminum oxide, aluminum nitride, germanium, indium phosphide, zinc oxide, or combinations thereof.

In some aspects, the techniques described herein relate to a semiconductor device, wherein the delta doping layer is formed from a donor material, an acceptor material, or a combination thereof.

In some aspects, the techniques described herein relate to a semiconductor device, wherein the active structure epitaxial layer includes boron, aluminum, gallium, indium, carbon, silicon, germanium, tin, nitrogen, phosphorus, oxygen, sulfur, selenium, tellurium, or combinations thereof.

In some aspects, the techniques described herein relate to a vertically-oriented semiconductor device, including: a substrate including silicon carbide; a buffer layer formed over the substrate; a delta doping layer formed over the buffer layer; and an active structure epitaxial layer including gallium oxide formed over the delta doping layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a flow diagram illustrating a method of forming a structure having a delta doping layer deposited between buffer layers, according to example embodiments.

FIGS. 2A-2E are block diagrams illustrating a structure corresponding to each step in the method of FIG. 1, according to example embodiments.

FIG. 3 illustrates a chart corresponding to an example process for depositing a delta doping layer, according to example embodiments.

FIG. 4 is a flow diagram illustrating a method of forming a structure having a delta doping layer deposited between buffer layers, according to example embodiments.

FIGS. 5A-5E are block diagrams illustrating a structure corresponding to each step in the method of FIG. 4, according to example embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Epitaxy generally refers to the process of growing a thin film of crystals of an active structure epitaxial layer (also referred to as an active layer) on a substrate material (also referred to as a substrate layer). Typically, both the active structure epitaxial layer and the substrate material are crystalline with defined lattice structures. During the growth process, an interface between the active layer and the substrate layer is created. At this interface, the respective lattices of the active layer and the substrate layer adapt themselves to each other through various distortions, thus creating defects which can capture and hold charge carriers, also referred to as trapping. In semiconductor devices, such defects or traps can significantly affect the performance of the semiconductor by impeding transport of charge carriers, resulting in a degradation of device performance. These traps may be electron traps or hole traps, and may occur in n-type materials (wherein charge carriers are electrons) and p-type materials (wherein charge carriers are holes, or positive charges). In some designs, a buffer layer may be grown or deposited between the active layer and the substrate layer. The buffer layer may be configured to improve or minimize the number of defects resulting from the differing crystal lattice structures of the gallium oxide and silicon carbide layers. However, as those skilled in the art understand, defects may still exist in the buffer layer due to the different crystal lattice structures, thus resulting in a similar degradation of performance.

Delta doping involves the formation of a thin layer of dopant atoms on a semiconductor material. The dopant atoms are used to modify the properties of the semiconductor material, such as its conductivity. The delta doping layer is typically formed by depositing a monolayer of dopant atoms on the surface of the semiconductor material. The delta doping layer can be used to fill electronically trapped charges in the semiconductor material, thereby improving the performance of the semiconductor device.

One or more techniques disclosed herein improve upon the conventional epitaxy process by introducing a delta doping layer in addition to a buffer layer to minimize the charge trapping effect caused by the differing crystal lattice structures between the substrate and the active layer. For example, the delta doping layer may be configured to fill electronic trapped charges in the buffer area to compensate for any lost local charge from the differing crystal lattice structures, thus easing the electric field sitting at the interface between the active and substrate layers.

This approach may be used to minimize charge trapping effects in various semiconductor devices, including diodes and transistors. It is contemplated that the embodiments of the present disclosure can be applied to a variety of semiconductor devices, including but not limited to Schottky barrier diodes, light-emitting diodes (LEDs), vertical-cavity surface-emitting lasers (VCSELs), field-effect transistors, metal-oxide-semiconductor field effect transistors (MOSFETs), trench MOSFETs, metal-insulator-semiconductor field effect transistors (MISFETs), metal-semiconductor field effect transistors (MESFETs), bipolar junction transistors, and the like. The orientation of the device may be vertical or planar. By applying the methods of the present disclosure to a semiconductor device, charge trapping effects can be mitigated, allowing the device to approach ideal behavior and allowing current to flow through the device with minimal perturbation. The methods of the present disclosure may result in an improvement in one or more device parameters, including but not limited to charge carrier mobility, on/off current ratio, subthreshold slope, and the like. The methods of the present disclosure may further improve heat dissipation throughout the device, allowing for higher temperature operation with minimal, if any, degradation in device performance. Self-heating effects may be reduced in the semiconductor devices prepared by the methods of the present disclosure, increasing the lifetime and the reliability of these devices.

There is provided a method of forming a semiconductor device, which includes loading a substrate into a process chamber, depositing a first buffer layer over the substrate, depositing a delta doping layer on the first buffer layer, depositing a second buffer layer on the delta doping layer, wherein the first buffer layer, the delta doping layer, and the second buffer layer form a buffer structure, and depositing an active structure epitaxial layer on the second buffer layer. In some embodiments, the semiconductor device is a vertically oriented semiconductor device. In some embodiments, the semiconductor device is a planar device. In some embodiments, the semiconductor device is an n-type device. In some embodiments, the semiconductor device is a p-type device.

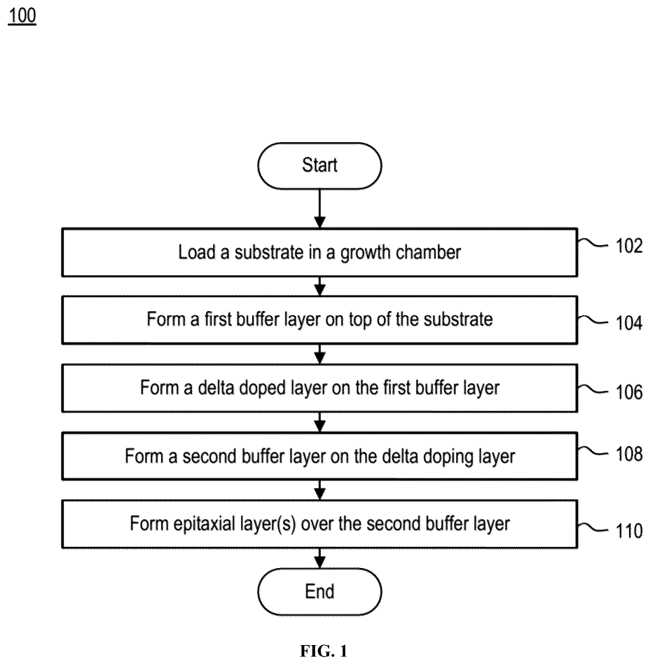

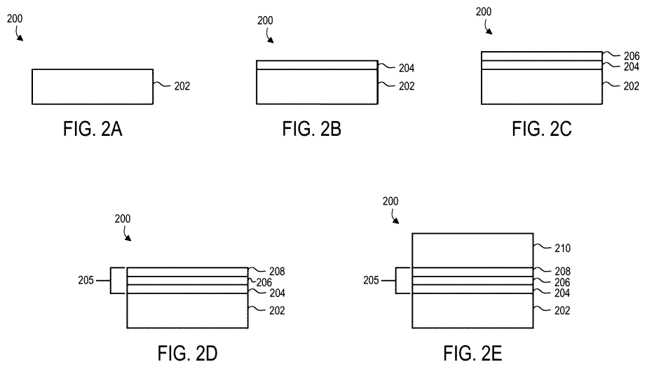

FIG. 1 is a flow diagram illustrating a method 100 of forming a vertically oriented semiconductor device, described as structure 200, having a delta doping layer deposited between buffer layers, according to example embodiments. FIGS. 2A-2E are block diagrams illustrating a progress of structure 200 corresponding to each step described above in method 100, according to example embodiments.

At step 102, a substrate 202 may be loaded into a process chamber. In some embodiments, substrate 202 may be formed from silicon carbide (SiC). In some embodiments, substrate 202 may be formed from silicon carbide, silicon germanium, silicon, gallium arsenide, sapphire, aluminum oxide, aluminum nitride, germanium, indium phosphide, zinc oxide, the like, or combinations thereof. In some embodiments, the substrate 202 may be selected based on the type of semiconductor device and other factors such as the identity of the active structure epitaxial layer and the desired device performance characteristics. In some embodiments, substrate 202 may have a thickness of about 100 nm to about 10 mm, about 100 nm, about 200 nm, about 300 nm, about 400 nm, about 500 nm, about 1 μm, about 10 μm, about 100 μm, about 200 μm, about 500 μm, about 1 mm, about 10 mm, or any value contained within a range formed by any two of the preceding values. In some embodiments, substrate 202 may have a different thickness, depending on the device type and application.

In some embodiments, the process chamber may be a plasma vapor deposition chamber, a chemical vapor deposition (CVD) chamber, a metal-organic chemical vapor deposition (MOCVD) chamber, a molecular beam epitaxy (MBE) chamber, a magneto luminous chemical vapor deposition (MLCVD) chamber, an ultra-high vacuum chamber, or, more generally, a reaction chamber.

At step 104, a first buffer layer 204 may be formed on substrate 202. For example, the first buffer layer 204 may be deposited over a top surface of substrate 202. In some embodiments, the first buffer layer 204 may be deposited uniformly over a top surface of substrate 202. In some embodiments, the first buffer layer 204 may be deposited selectively over a top surface of substrate 202. For example, the first buffer layer 204 may be deposited selectively in a pattern. During processing, the first buffer layer 204 may be grown on substrate 202. In some embodiments, the first buffer layer 204 may be formed from an alloy. In some embodiments, the first buffer layer 204 may be an electrically conductive material. In some embodiments, the first buffer layer may include aluminum gallium oxide (AGO). For example, the first buffer layer may include (Al₍₁₋ₓ₎Ga₍ₓ₎)_{(y)}O_{(y-1)}, wherein x and y are integers and may vary. Other buffer materials may also be used, depending on the specific device architecture and materials. In some embodiments, the first buffer layer 204 may have a thickness of about 1 nm to about 5 nm, such as about 1 nm, about 2 nm, about 3 nm, about 4 nm, about 5 nm, or any value contained within a range formed by any two of the preceding values.

At step 106, a delta doping layer 206 may be formed on first buffer layer 204. For example, the delta doping layer 206 may be deposited over a top surface of first buffer layer 204. Delta doping layer 206 may be configured to fill electronic trapped charges in first buffer layer 204 and/or substrate 202 to compensate for any lost local charge from the differing crystal lattice structures between these materials. In this manner, delta doping layer 206 may minimize charge trapping therefore ease the electric field at the interface between the eventual active structure epitaxial layer and substrate 202. The delta doping layer 206 may allow for near ideal current flow through the interface of the active structure epitaxial layer and substrate 202. In some embodiments, delta doping layer 206 may be formed from a material or element dependent on the type of defects that may be present. For example, in some embodiments, delta doping layer 206 may include an acceptor material or a donor material. In some embodiments, the delta doping layer 206 can include, but is not limited to, silicon, magnesium, beryllium, the like, or combinations thereof. In some embodiments, delta doping layer 206 may have a thickness of one monolayer. In some embodiments, delta doping layer 206 may have a thickness greater than a monolayer. In some embodiments, delta doping layer 206 may have a thickness of less than a monolayer, such that less than 100% of the atoms in a monolayer of the first buffer layer 204 is replaced with the atoms of the delta doping layer 206. For example, in some embodiments, about 30%, about 40%, about 50%, about 60%, about 70%, about 80%, about 90%, or any value contained within a range formed by any two of the preceding values, of the atoms in a monolayer of the first buffer layer 204 is replaced with the atoms of the delta doping layer 206.

At step 108, a second buffer layer 208 may be formed on substrate 202. For example, a second buffer layer 208 may be deposited over a top surface of delta doping layer 206. In some embodiments, the second buffer layer 208 may be deposited uniformly over a top surface of delta doping layer 206. In some embodiments, the second buffer layer 208 may be deposited selectively over a top surface of delta doping layer 206. For example, the second buffer layer 208 may be deposited selectively in a pattern. During processing, second buffer layer 208 may be grown on substrate 202 in a manner similar to first buffer layer 204. In some embodiments, the second buffer layer 208 may be formed from an alloy. In some embodiments, the second buffer layer 208 may be an electrically conductive material. In some embodiments, the second buffer layer may include aluminum gallium oxide (AGO). For example, the second buffer layer may include (Al₍₁₋ₓ₎Ga₍ₓ₎)_{(y)}O_{(y-1)}, wherein x and y are integers and may vary. In aluminum gallium oxide compositions, it is contemplated that the second buffer may be different from the first buffer layer, such that one or more of x and y may be different values in the first buffer layer and the second buffer layer. In some embodiments, second buffer layer 208 may have a thickness of about 1 nm to about 5 nm, such as about 1 nm, about 2 nm, about 3 nm, about 4 nm, about 5 nm, or any value contained within a range formed by any two of the preceding values. In some embodiments, the second buffer layer 208 may be formed from the same material as the first buffer layer 204. In some embodiments, the second buffer layer 208 may be formed from a different material as the first buffer layer 204. In some embodiments, the first buffer layer 204 and the second buffer layer 208 have the same thickness. In some embodiments, the first buffer layer 204 and the second buffer layer 208 have different thicknesses.

First buffer layer 204, delta doping layer 206, and second buffer layer 208 may collectively form a buffer structure 205. In some embodiments, buffer structure 205 may have a total thickness of about 2 nm to about 15 nm, such as about 2 nm, about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, or any value contained within a range formed by any two of the preceding values. As described above, the buffer structure 205 may have a gradient composition, wherein the first buffer layer 204 and the second buffer layer 208 may be formed from different materials or have a different composition.

In some embodiments, the structure 200 may include a plurality of first buffer layers 204, delta doping layers 206, second buffer layers 208, or combinations thereof. In some embodiments, the structure 200 may include a substrate 202, a first buffer layer 204, a delta doping layer 206, a second buffer layer 208, another delta doping layer 206, and another second buffer layer 208. The delta doping layer 206 and the second buffer layer 208, or the buffer structure 205, may be repeated in the structure 200 one time, two times, three times, four times, five times, and so forth. It is contemplated that defects or dislocations between the substrate and the buffer layer may be present, and that as each successive layer is deposited, the density of defects decreases along the vertical growth axis. However, including multiple layers of delta doping material and buffers, by repeating buffer structure 205, can minimize these effects and allow the performance of the semiconductor device to approach ideal behavior. The thickness and composition of each of buffer structure 205 may be varied in each successive layer, if multiple buffer structures 205 are included. In this way, the plurality of buffer structures can compensate for the varying density of defects along the vertical growth axis.

At step 110, an active structure epitaxial layer 210 may be formed on substrate 202. For example, the active structure epitaxial layer 210 may be deposited over a top surface of second buffer layer 208. In some embodiments, active structure epitaxial layer 210 may be formed from a material dependent upon the device type and application. For example, different materials may be used in the active structure epitaxial layer in Schottky diodes than used in MOSFETs. Any such materials are within the scope of the present disclosure. In some embodiments, active structure epitaxial layer 210 may include boron, aluminum, gallium, indium, carbon, silicon, germanium, tin, nitrogen, phosphorus, oxygen, sulfur, selenium, tellurium, or combinations thereof. Alloys, composites, and the like of these elements are contemplated and within the scope of this disclosure. Alloys, composites, and the like containing at least one of the aforementioned elements, in combination with other elements, are also contemplated and within the scope of this disclosure. In some embodiments, active structure epitaxial layer 210 may be formed from gallium oxide (GaO). In some embodiments, active structure epitaxial layer 210 may have a thickness about 10 nm to about 100 nm, such as about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, or any value contained within a range formed by any two of the preceding values.

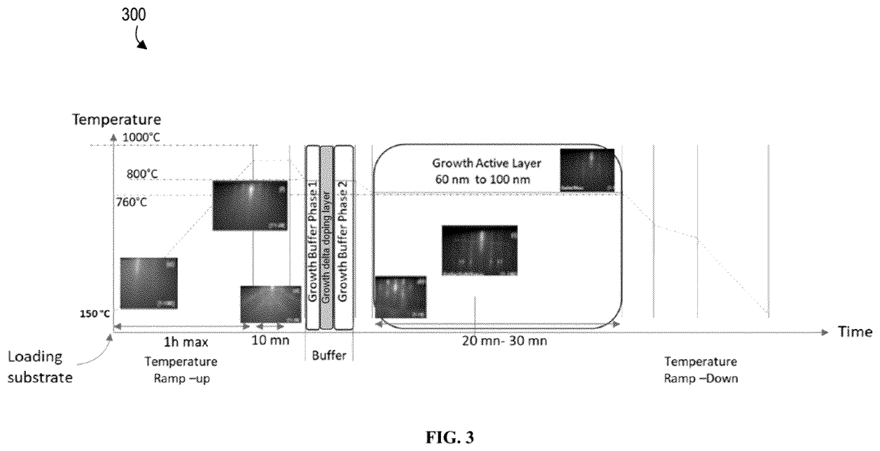

FIG. 3 illustrates a chart 300 corresponding to a process for depositing a delta doping layer, according to an embodiment of the present disclosure. In some embodiments, the process may correspond to method 100 discussed above in conjunction with FIG. 1.

As shown, a substrate may be loaded in a process chamber at time 0. The temperature in the process chamber may be adjusted to a temperature sufficient for depositing a first buffer layer, followed by the delta doping layer, and the second buffer layer, thus forming the buffer structure. Processing may continue with an active structure epitaxial layer being deposited over the second buffer layer and grown until it achieves a desired thickness.

In some embodiments, the temperature in the process chamber may be adjusted from about 100° C. to about 1200° C., such as about 100° C., about 150° C., about 200° C., about 250° C., about 300° C., about 350° C., about 400° C., about 450° C., about 500° C., about 550° C., about 600° C., about 650° C., about 700° C., about 750° C., about 800° C., about 850° C., about 900° C., about 950° C., about 1000° C., about 1100° C., about 1200° C., or any value contained within a range formed by any two of the preceding values. The process may include temperature adjustments when the substrate is loaded, when the substrate is prepared for deposition of the first buffer layer, when the first buffer layer is deposited, when the delta doping layer is deposited, when the second buffer layer is deposited, when the active structure epitaxial layer is deposited, and when the active structure epitaxial layer is grown. Additional temperature adjustments may occur during the above time points.

In some embodiments, the process chamber may have a controlled pressure and atmosphere. For example, in some embodiments, an inert atmosphere may be maintained within the process chamber. In some embodiments, the pressure within the process chamber may be controlled to maintain a vacuum.

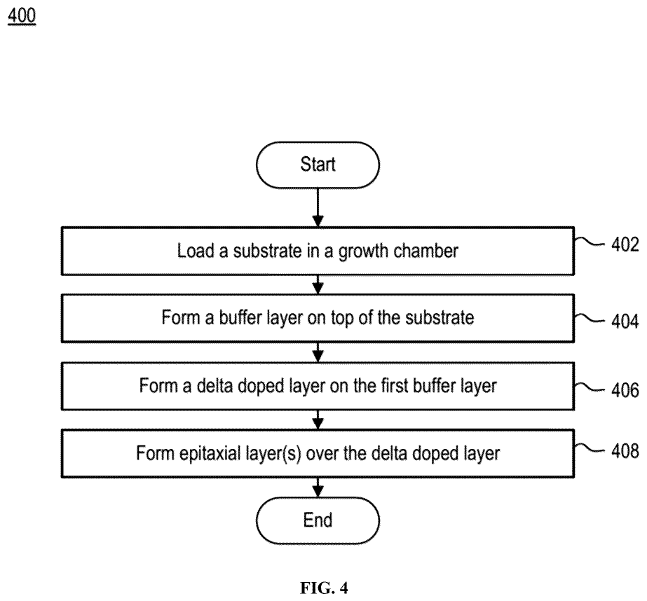

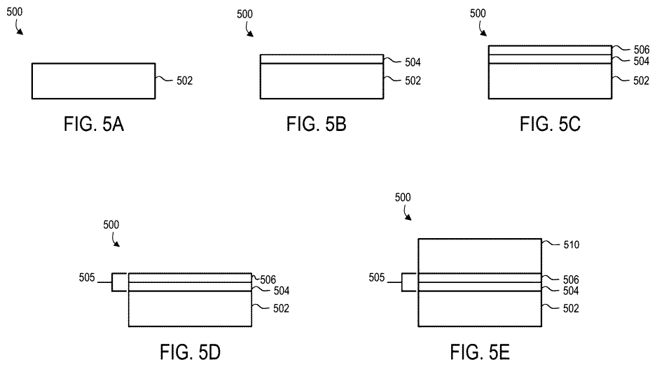

FIG. 4 is a flow diagram illustrating a method 400 of forming a vertically oriented semiconductor device having a delta doping layer, according to example embodiments. FIGS. 5A-5E are block diagrams illustrating a progress of a vertically oriented semiconductor, described as structure 500, corresponding to each step described above in method 400, according to example embodiments.

At step 402, a substrate 502 may be loaded into a process chamber for growing an active structure epitaxial layer. In some embodiments, substrate 502 may be formed from silicon carbide (SiC). In some embodiments, substrate 502 may be formed from silicon carbide, silicon germanium, silicon, gallium arsenide, sapphire, aluminum oxide, aluminum nitride, germanium, indium phosphide, zinc oxide, the like, or combinations thereof. In some embodiments, the substrate 502 may be selected based on the type of semiconductor device and other factors such as the identity of the active structure epitaxial layer and the desired device performance characteristics. In some embodiments, substrate 502 may have a thickness of about 10 nm to about 10 mm, such as about 10 nm, about 50 nm, about 100 nm, about 200 nm, about 300 nm, about 400 nm, about 500 nm, about 1 μm, about 10 μm, about 100 μm, about 500 μm, about 1 mm, about 10 mm, or any value contained within a range formed by any two of the preceding values. In some embodiments, substrate 502 may have a different thickness, depending on the device type and application.

At step 404, a buffer layer 504 may be formed on substrate 502. For example, the buffer layer 504 may be deposited over a top surface of substrate 502. In some embodiments, the buffer layer 504 may be deposited uniformly over a top surface of substrate 502. In some embodiments, the buffer layer 504 may be deposited selectively over a top surface of substrate 502. For example, the buffer layer 504 may be deposited selectively in a pattern. During processing, buffer layer 504 may be grown on substrate 502. In some embodiments, the buffer layer may include aluminum gallium oxide (AGO). For example, the buffer layer may include (Al₍₁₋ₓ₎Ga₍ₓ₎)_{(y)}O_{(y-1)}, wherein x and y are integers and may vary. In some embodiments, buffer layer 504 may have a thickness of about 1 nm to about 5 nm, such as about 1 nm, about 2 nm, about 3 nm, about 4 nm, about 5 nm, or any value contained within a range formed by any two of the preceding values.

At step 406, a delta doping layer 506 may be formed on buffer layer 504. Delta doping layer 506 may be configured to fill electronic trapped charges in buffer layer 504 and/or substrate 502 to compensate for any lost local charge from the differing crystal lattice structures. In some embodiments, delta doping layer 506 may be formed from materials described herein with respect to delta doping layer 506, such as a material dependent on the type of defects that may be present. For example, in some embodiments, delta doping layer 506 may include an acceptor material or a donor material. In some embodiments, the delta doping material of delta doping layer 506 can include but is not limited to silicon, magnesium, beryllium, the like, or combinations thereof.

Buffer layer 504 and delta doping layer 506 may collectively form a buffer structure 505. In some embodiments, buffer structure 505 may have a total thickness of about 2 nm to about 15 nm, such as about 2 nm, about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, or any value contained within a range formed by any two of the preceding values.

In some embodiments, the structure 500 may include a plurality of first buffer layers 504, delta doping layers 506, or combinations thereof. In some embodiments, the structure 500 may include a plurality of buffer structures 505. In some embodiments, the structure 500 may include a substrate 502, a buffer layer 504, a delta doping layer 506, another buffer layer 504, and another delta doping layer 506. The buffer layer 504 and the delta doping layer 506, or the buffer structure 505, may be repeated in the structure 500 one time, two times, three times, four times, five times, and so forth. It is contemplated that defects or dislocations between the substrate and the buffer layer may be present, and thus including multiple layers of delta doping material and buffer can minimize these effects.

At step 408, an active structure epitaxial layer 510 may be formed on substrate 502. For example, an active structure epitaxial layer 510 may be deposited over a top surface of delta doping layer 506. In some embodiments, active structure epitaxial layer 510 may be formed from a material dependent upon the device type and application. In some embodiments, active structure epitaxial layer 510 may include boron, aluminum, gallium, indium, carbon, silicon, germanium, tin, nitrogen, phosphorus, oxygen, sulfur, selenium, tellurium, or combinations thereof. Alloys, composites, and the like of these elements are contemplated and within the scope of this disclosure. Alloys, composites, and the like containing at least one of the aforementioned elements, in combination with other elements, are also contemplated and within the scope of this disclosure. In some embodiments, active structure epitaxial layer 510 may be formed from GaO. In some embodiments, active structure epitaxial layer 510 may have a thickness of about 10 nm to about 100 nm, such as about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, or any value contained within a range formed by any two of the preceding values.

In some embodiments, there is provided a method of minimizing charge trapping at a heterojunction in a semiconductor device, which includes applying a first buffer layer to a substrate, applying a delta doping layer to the first buffer layer, and applying an active structure epitaxial layer to the delta doping layer. In some embodiments, the method may further include applying a second buffer layer between the delta doping layer and the active structure epitaxial layer, thereby forming a buffer structure including the first buffer layer, the delta doping layer, and the second buffer layer. In some embodiments, the method includes applying a plurality of buffer structures. The first buffer layer, the delta doping layer, and the second buffer layer may be formed from any of the materials described herein. In some embodiments, the semiconductor device is a vertically oriented semiconductor device. In some embodiments, the semiconductor device is an n-type device. In some embodiments, the semiconductor device is a p-type device.

In some embodiments, there is provided a method of reducing thermal effects in a semiconductor device, which includes applying a first buffer layer to a substrate, applying a delta doping layer to the first buffer layer, and applying an active structure epitaxial layer to the delta doping layer. Reducing thermal effects in the semiconductor device can include reduced self-heating, improved heat dissipation, the ability to operate the semiconductor device at a higher temperature, or combinations thereof. In some embodiments, the method may further include applying a second buffer layer between the delta doping layer and the active structure epitaxial layer. In some embodiments, the semiconductor device is a diode, such as a Schottky barrier diode. In some embodiments, the semiconductor device is a transistor, such as a MOSFET. In some embodiments, the semiconductor device is a vertically oriented semiconductor device. In some embodiments, the semiconductor device is an n-type device. In some embodiments, the semiconductor device is a p-type device. The first buffer layer, the delta doping layer, and the second buffer layer may be formed from any of the materials described herein. The improved performance may include an improvement in one or more device parameters, including but not limited to charge carrier mobility, on/off current ratio, subthreshold slope, and the like.

In some embodiments, there is provided a method of preparing a device, which includes applying a first buffer layer to a substrate, applying a delta doping layer to the first buffer layer, and applying an active structure epitaxial layer to the delta doping layer, thereby preparing the semiconductor device, wherein the semiconductor device exhibits improved performance relative to a semiconductor device which does not include a delta doping layer. In some embodiments, the method may further include applying a second buffer layer between the delta doping layer and the active structure epitaxial layer. In some embodiments, the semiconductor device is a diode, such as a Schottky barrier diode. In some embodiments, the semiconductor device is a transistor, such as a MOSFET. In some embodiments, the semiconductor device is a vertically oriented semiconductor device. In some embodiments, the semiconductor device is an n-type device. In some embodiments, the semiconductor device is a p-type device. The first buffer layer, the delta doping layer, and the second buffer layer may be formed from any of the materials described herein. The improved performance may include an improvement in one or more device parameters, including but not limited to charge carrier mobility, on/off current ratio, subthreshold slope, and the like.

There is provided a semiconductor device which includes a substrate, a buffer layer formed over the substrate, a delta doping layer formed over the buffer layer, and an active structure epitaxial layer formed over the delta doping layer. In some embodiments, there is provided a semiconductor device which includes a silicon carbide substrate, a buffer layer formed over the substrate, a delta doping layer formed over the buffer layer, and a gallium oxide active structure epitaxial layer formed over the delta doping layer. In some embodiments, the semiconductor device is vertically oriented; in other embodiments, the semiconductor device is planar. The buffer layer and delta doping layers may be formed from any of the materials disclosed herein. In some embodiments, the delta doping layer includes silicon. In some embodiments, the semiconductor device includes a plurality of delta doping layers, a plurality of buffer layers, or a combination thereof. In some embodiments, the semiconductor device is an n-type device. In some embodiments, the semiconductor device is a p-type device.

When used in combination with gallium oxide as described herein, silicon carbide offers several advantages over other substrate materials, including high thermal conductivity, along with improved heat dissipation and reduced self-heating effects in devices. Compared to materials typically used as substrates for gallium oxide, such as sapphire, there is less lattice mismatch between silicon carbide and gallium oxide, meaning fewer defects at the interface. While gallium oxide substrates can be used in combination with gallium oxide active layers, silicon carbide is less expensive and more widely available as a substrate material. The combination of silicon carbide (wide bandgap) and gallium oxide (ultrawide bandgap) further allows for devices suited to high-power and high-voltage applications.

The present disclosure includes, but is not limited to, the following embodiments.
1. A method of forming a semiconductor device, comprising: loading a substrate into a process chamber; depositing a first buffer layer over the substrate; depositing a delta doping layer on the first buffer layer; depositing a second buffer layer on the delta doping layer, wherein the first buffer layer, the delta doping layer, and the second buffer layer form a buffer structure; and depositing an active structure epitaxial layer on the second buffer layer.
2. The method of embodiment 1, wherein the semiconductor device is vertically oriented.
3. The method of embodiment 1 or 2, wherein the substrate comprises silicon carbide, silicon germanium, silicon, gallium arsenide, sapphire, aluminum oxide, aluminum nitride, germanium, indium phosphide, zinc oxide, or combinations thereof.
4. The method of any of embodiments 1 through 3, wherein the delta doping layer comprises a donor material, an acceptor material, or a combination thereof.
5. The method of any of embodiments 1 through 4, wherein the delta doping layer has a thickness of a monolayer.
6. The method of any of embodiments 1 through 5, further comprising depositing a plurality of delta doping layers, a plurality of second buffer layers, or a combination thereof.
7. The method of any of embodiments 1 through 6, wherein the active structure epitaxial layer comprises boron, aluminum, gallium, indium, carbon, silicon, germanium, tin, nitrogen, phosphorus, oxygen, sulfur, selenium, tellurium, or combinations thereof.
8. The method of any of embodiments 1 through 7, wherein a temperature within the process chamber is about 100° C. to about 1200° C.
9. A method of epitaxially forming a semiconductor device, comprising: loading a substrate into a process chamber; depositing a buffer layer over the substrate; depositing a delta doping layer on the buffer layer, the buffer layer and the delta doping layer forming a buffer structure; and depositing an active structure epitaxial layer on the delta doping layer.
10. The method of embodiment 9, wherein the semiconductor device is vertically oriented.
11. The method of embodiment 9 or 10, wherein the substrate comprises silicon carbide, silicon germanium, silicon, gallium arsenide, sapphire, aluminum oxide, aluminum nitride, germanium, indium phosphide, zinc oxide, or combinations thereof.
12. The method of any of embodiments 9 through 11, wherein the delta doping layer comprises a donor material, an acceptor material, or a combination thereof.
13. The method of any of embodiments 9 through 12, wherein the delta doping layer has a thickness of a monolayer.
14. The method of any of embodiments 9 through 13, further comprising depositing a plurality of delta doping layers, a plurality of buffer layers, or a combination thereof.
15. The method of any of embodiments 9 through 14, wherein the active structure epitaxial layer comprises boron, aluminum, gallium, indium, carbon, silicon, germanium, tin, nitrogen, phosphorus, oxygen, sulfur, selenium, tellurium, or combinations thereof.
16. The method of any of embodiments 9 through 15, wherein a temperature within the process chamber is about 100° C. to about 1200° C.
17. A semiconductor device, comprising: a substrate; a buffer layer formed over the substrate; a delta doping layer formed over the buffer layer; and an active structure epitaxial layer formed over the delta doping layer.
18. The semiconductor device of embodiment 17, wherein the semiconductor device is vertically oriented.
19. The semiconductor device of embodiment 17 or 18, further comprising a second buffer layer formed between the delta doping layer and the active structure epitaxial layer.
20. The semiconductor device of any of embodiments 17 through 19, wherein the substrate comprises silicon carbide, silicon germanium, silicon, gallium arsenide, sapphire, aluminum oxide, aluminum nitride, germanium, indium phosphide, zinc oxide, or combinations thereof.
21. The semiconductor device of any of embodiments 17 through 20, wherein the delta doping layer is formed from a donor material, an acceptor material, or a combination thereof.
22. The semiconductor device of any of embodiments 17 through 21, wherein the active structure epitaxial layer comprises boron, aluminum, gallium, indium, carbon, silicon, germanium, tin, nitrogen, phosphorus, oxygen, sulfur, selenium, tellurium, or combinations thereof.
23. The semiconductor device of any of embodiments 17 through 22, further comprising a plurality of delta doping layers, a plurality of buffer layers, or a combination thereof.
24. A semiconductor device, comprising: a substrate comprising silicon carbide; a buffer layer formed over the substrate; a delta doping layer formed over the buffer layer; and an active structure epitaxial layer comprising gallium oxide formed over the delta doping layer.
25. The semiconductor device of embodiment 24, wherein the semiconductor device is vertically oriented.
26. The semiconductor device of embodiment 24 or 25, further comprising: a second buffer layer formed between the delta doping layer and the active structure epitaxial layer.
27. The semiconductor device of any of embodiments 24 through 26, wherein the delta doping layer comprises silicon.
28. The semiconductor device of any of embodiments 24 through 27, further comprising a plurality of delta doping layers, a plurality of buffer layers, or a combination thereof.

While the foregoing is directed to embodiments of the present disclosure, other and further embodiments of the disclosure may be devised without departing from the basic scope thereof, and the scope thereof is determined by the claims that follow.

This disclosure is not limited to the particular systems, devices and methods described, as these may vary. The terminology used in the description is for the purpose of describing the particular versions or embodiments only and is not intended to limit the scope.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

As used herein, the term “about” means plus or minus up to 20% of the numerical value of the number with which it is being used. For example, “about 50%” means in the range of 40-60% and includes exactly 50%. The term “about” may refer to plus or minus 1%, 5%, 10%, 15%, or 20% of the numerical value of the number with which it is being used.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” et cetera). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups. It will be further understood by those within the art that if a specific number of an introduced claim recitation is intended, such an intent will be explicitly recited in the claim, and in the absence of such recitation no such intent is present.

For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, et cetera” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, et cetera). In those instances where a convention analogous to “at least one of A, B, or C, et cetera” is used, in general such a construction is intended in the sense one having skill in the art would understand the convention (for example, “a system having at least one of A, B, or C” would include but not be limited to systems that have A alone, B alone, C alone, A and B together, A and C together, B and C together, and/or A, B, and C together, et cetera). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, et cetera. As a non-limiting example, each range discussed herein can be readily broken down into a lower third, middle third and upper third, et cetera. As will also be understood by one skilled in the art all language such as “up to,” “at least,” and the like include the number recited and refer to ranges that can be subsequently broken down into subranges as discussed above. Finally, as will be understood by one skilled in the art, a range includes each individual member. Thus, for example, a group having 1-3 compounds refers to groups having 1, 2, or 3 compounds. Similarly, a group having 1-5 cells refers to groups having 1, 2, 3, 4, or 5 compounds, and so forth.

Various of the above-disclosed and other features and functions, or alternatives thereof, may be combined into many other different systems or applications. Various presently unforeseen or unanticipated alternatives, modifications, variations, or improvements therein may be subsequently made by those skilled in the art, each of which is also intended to be encompassed by the disclosed embodiments.

What is claimed is:

1. A method of forming a semiconductor device, comprising:
loading a substrate into a process chamber;
depositing a first buffer layer over the substrate;
depositing a delta doping layer on the first buffer layer;
depositing a second buffer layer on the delta doping layer, wherein the first buffer layer, the delta doping layer, and the second buffer layer form a buffer structure; and
depositing an active structure epitaxial layer on the second buffer layer.

2. The method of claim 1, wherein the semiconductor device is vertically oriented.

3. The method of claim 1, wherein the substrate comprises silicon carbide, silicon germanium, silicon, gallium arsenide, sapphire, aluminum oxide, aluminum nitride, germanium, indium phosphide, zinc oxide, or combinations thereof.

4. The method of claim 1, wherein the delta doping layer comprises a donor material, an acceptor material, or a combination thereof.

5. The method of claim 1, wherein the active structure epitaxial layer comprises boron, aluminum, gallium, indium, carbon, silicon, germanium, tin, nitrogen, phosphorus, oxygen, sulfur, selenium, tellurium, or combinations thereof.

6. The method of claim 1, wherein a temperature within the process chamber is about 100° C. to about 1200° C.

7. A method of epitaxially forming a semiconductor device, comprising:
loading a substrate into a process chamber;
depositing a buffer layer over the substrate;
depositing a delta doping layer on the buffer layer, the buffer layer and the delta doping layer forming a buffer structure; and
depositing an active structure epitaxial layer on the delta doping layer.

8. The method of claim 7, wherein the semiconductor device is vertically oriented.

9. The method of claim 7, wherein the substrate comprises silicon carbide, silicon germanium, silicon, gallium arsenide, sapphire, aluminum oxide, aluminum nitride, germanium, indium phosphide, zinc oxide, or combinations thereof.

10. The method of claim 7, wherein the delta doping layer comprises a donor material, an acceptor material, or a combination thereof.

11. The method of claim 7, further comprising depositing a plurality of delta doping layers, a plurality of buffer layers, or a combination thereof.

12. The method of claim 7, wherein the active structure epitaxial layer comprises boron, aluminum, gallium, indium, carbon, silicon, germanium, tin, nitrogen, phosphorus, oxygen, sulfur, selenium, tellurium, or combinations thereof.

13. The method of claim 7, wherein a temperature within the process chamber is about 100° C. to about 1200° C.

14. A semiconductor device, comprising:
a substrate;
a buffer layer formed over the substrate;
a delta doping layer formed over the buffer layer; and
an active structure epitaxial layer formed over the delta doping layer.

15. The semiconductor device of claim 14, wherein the semiconductor device is vertically oriented.

16. The semiconductor device of claim 14, further comprising:
a second buffer layer formed between the delta doping layer and the active structure epitaxial layer.

17. The semiconductor device of claim 14, wherein the substrate comprises silicon carbide, silicon germanium, silicon, gallium arsenide, sapphire, aluminum oxide, aluminum nitride, germanium, indium phosphide, zinc oxide, or combinations thereof.

18. The semiconductor device of claim 14, wherein the delta doping layer is formed from a donor material, an acceptor material, or a combination thereof.

19. The semiconductor device of claim 14, wherein the active structure epitaxial layer comprises boron, aluminum, gallium, indium, carbon, silicon, germanium, tin, nitrogen, phosphorus, oxygen, sulfur, selenium, tellurium, or combinations thereof.

20. A vertically-oriented semiconductor device, comprising:
a substrate comprising silicon carbide;
a buffer layer formed over the substrate;
a delta doping layer formed over the buffer layer; and
an active structure epitaxial layer comprising gallium oxide formed over the delta doping layer.
